(19) United States
(12) Patent Application Publication
(10) Pub. No.: US 2006/0120051 A1
(43) Pub. Date: Jun. 8, 2006

(54) Liquid metal thermal interface material system

(76) Inventors: Chris Macris, North Bend, WA (US); Thomas R. Sanderson, Issaquah, WA (US); Robert G. Ebel, Seattle, WA (US)

Correspondence Address: Robert A. Jensen;Jensen & Puntigam, P.S., #1020, 2033 6th Ave., Seattle, WA, 98121, US

(21) Appl. No.: 11/004,017

(22) Filed: Dec. 3, 2004

(51) Int. Cl. H05K 7/20

(52) U.S. Cl. 361/704

(57) ABSTRACT

A metal thermal interface structure for dissipating heat from electronic components comprised a heat spreader lid, metal alloy that is liquid over the operating temperature range of the electronic component, and design features to promote long-term reliability and high thermal performance.

### TECHNICAL FIELD

This invention relates to the field of heat transfer structures between electronic components and their associated heat exchangers and, more particularly, to a thermal interface system which utilizes a metal alloy interface, materials and design features to stabilize the alloy while exposed to various environmental conditions.

### BACKGROUND OF THE INVENTION

Today's electronic components generate significant amounts of heat which must be removed to maintain the component's junction temperature within safe operating limits. Failure to effectively conduct away heat leaves these devices at high operating temperatures, ultimately resulting in decreased performance and reliability.

The heat removal process involves heat conduction between the electronic component and heat exchanger, or heat sink, via a thermal interface material. Small irregularities and surface asperities on both the component and heat sink surfaces create air gaps and therefore increase the resistance to the flow of heat. The thermal resistance of the interface between these two surfaces can be reduced by providing an interface material which fills the air gaps and voids in the surfaces.

An ideal medium for transferring heat from one surface to another should have low interfacial or contact thermal resistance, high bulk thermal conductivity and the ability to achieve a minimum bond-line thickness. Additional desirable qualities include product stability, ease of deployment, product reworkability, low cost and non-toxicity.

Liquids have low interfacial resistance because they wet a surface forming a continuous contact with a large area. Most liquids do not, however, have very high conductivity. Solids, and in particular metals, have very high conductivity but high interfacial resistance. Most common heat transfer materials combine highly conductive particles with a liquid or plastic in order to exploit both characteristics. Examples of the former are greases and gels while the latter include filled epoxies, silicones and acrylics.

Greases have been developed with thermal conductivities significantly better than the corresponding conductivities of filled adhesives. Typical problems with greases include pumping and dry out, both of which can cause the conducting medium to lose contact with one or both of the heat transfer surfaces. Pumping occurs when the structure is deformed, due to differential thermal expansion or mechanical loads, and the grease is extruded. The oils contained in a grease can be depleted by evaporation or by separation and capillary flow.

Liquid metal alloys (liquid at the operating temperature of the electronic component), such as alloys of bismuth, gallium and indium, potentially offer both low interfacial resistance and high conductivity. Several alloys of gallium with very low melting points have also been identified as potential liquid metal interface materials. Thermal performance of such an interface would be more than one order of magnitude greater than many adhesives typically in use.

Although liquid metal alloys offer both low interfacial resistance and high conductivity, they have historically suffered from various reliability issues including corrosion/oxidation, intermetallic formation, drip-out, dewetting, and migration. Unless mitigated, these mechanisms will continue to degrade the interface, resulting in a thermally related catastrophic failure of the actual electronic component.

The ability to contain an electrically conductive liquid within an electronic package presents significant challenges. The liquid must be reliably retained in its enclosure throughout the life of the package if shorting is to be avoided. In addition, air must be excluded from the space between the heat transfer surfaces if the effective resistance is to be minimized. This is difficult due to the volume expansion of the liquid and is exacerbated if the metal changes between the liquid and the solid state within the temperature range of the package.

U.S. Pat. No. 4,092,697, granted to Spaight on May 30, 1978 discloses a conductive or non-conductive film (plastic or metallic) whose perimeter is attached to a heat sink surface thereby creating a pouch. Grease, powdered metal or low melt alloy is inserted within the pouch while the film interfaces the chip or source to be cooled. This design would prevent the interface material from migrating.

U.S. Pat. No. 4,233,645, granted to Balderes, et al. on Nov. 11, 1980 discloses a deformable heat transfer member (between a heat source and heat exchanger) comprised of a porous block of material and thermally conductive liquid retained within the block by surface tension. This design would also prevent the liquid interface material from migrating out of the thermal joint.

U.S. Pat. No. 4,323,914, granted to Berndlmaier, et al. on Apr. 6, 1982 discloses methods of protecting both a chip and heat exchanger from gallium-indium or mercury based alloys by coating the interface surfaces with parylene and chromium metal.

U.S. Pat. No. 4,915,177, granted to Altoz, et al. on Apr. 10, 1990 discloses a low melting point thermal interface material which is contained between the heat source and heat exchanger by applying a sealant to completely encapsulate the interface material.

U.S. Pat. No. 5,198,189, granted to Booth, et al. on Mar. 30, 1993 discloses a gallium-indium alloy with non-reactive particles which are added in order to increase the viscosity of the alloy and mitigate migration of material from the thermal joint.

U.S. Pat. No. 6,343,647, granted to Kim, et al. on Feb. 5, 2002 discloses a liquid metal interface material in which the alloy's operating temperature falls between its liquidus and solidus point, thereby reducing the amount of oxidation and increasing the alloy's viscosity.

U.S. Pat. No. 6,372,997, granted to Hill, et al. on Apr. 16, 2002 discloses a low melting point alloy coating both sides of a surface enhanced metallic foil, thereby providing a carrier to support and contain the liquid metal alloy.

U.S. Pat. No. 6,656,770, granted to Atwood, et al. on Dec. 2, 2003 discloses both a solder-based seal (between the ceramic cap/heat exchanger and package substrate) and an elastomeric gasket (between the ceramic cap/heat exchanger and chip) to near hermetically seal the cavity containing a Gallium alloy interface material and thereby limit ingress of oxygen, oxidation and migration.

U.S. Pat. No. 6,665,186, granted to Calmidi, et al. on Dec. 16, 2003 discloses a gallium based interface material held in place by a flexible seal, such as an O-ring, which also accommodates expansion and contraction of the liquid.

### SUMMARY OF THE INVENTION

Accordingly, it is the overall feature of the present invention to provide an improved thermal interface system in order to more effectively transfer thermal energy from an electronic component to a heat exchange structure.

One feature of the present invention is to provide an improved thermal interface system comprised of a metal interface which exhibits a high degree of surface wetting and possessing relatively high bulk thermal conductivity.

An additional feature of the present invention is to provide an improved metal thermal interface system which is liquid over the operating temperature of the electronic component, thereby minimizing the stresses placed on the electronic component by the heat exchange structure.

Yet, another feature of the present invention is to provide an improved metal thermal interface system which utilizes diffusion barrier layers to promote chemical compatibility between the metal interface and heat exchange components.

A further feature of the present invention is to provide an improved metal thermal interface system which includes materials and design features, such as moisture seals, encapsulants, desiccants and corrosion inhibitors, to promote long-term stability and reliability by mitigating corrosion.

Still another feature of the present invention is to provide an improved metal thermal interface system which includes barrier structures to preclude metal interface migration and preserve high heat transfer.

Lastly, it is a feature of the present invention to combine all of these unique design aspects and individual fabrication techniques into effective and manufacturable thermal interface system for electronic components, including Flip Chip and Cavity-Down IC packages.

### BRIEF DESCRIPTION OF THE DRAWINGS

FIG. 1 illustrates an electronic component package including a heat spreader lid, corrosion inhibitor and metal interface material comprising the thermal interface structure embodiment of the present invention.

FIGS. 2a and 2b illustrate the use of a metal interface barrier structure within the present invention.

FIG. 3 illustrates another heat spreader lid embodiment of the present invention.

FIG. 4 illustrates another electronic component package embodiment comprising an IC die and thermal interface structure.

### DETAILED DESCRIPTION OF THE INVENTION

Described below are several embodiments of the present invention which illustrate various ways the present invention can be implemented. In the descriptions that follow, like numerals represent like numerals in all figures. For example, where the numeral 14 is used to refer to a particular element in one figure, the numeral 14 appearing in any other figure refers to the same element.

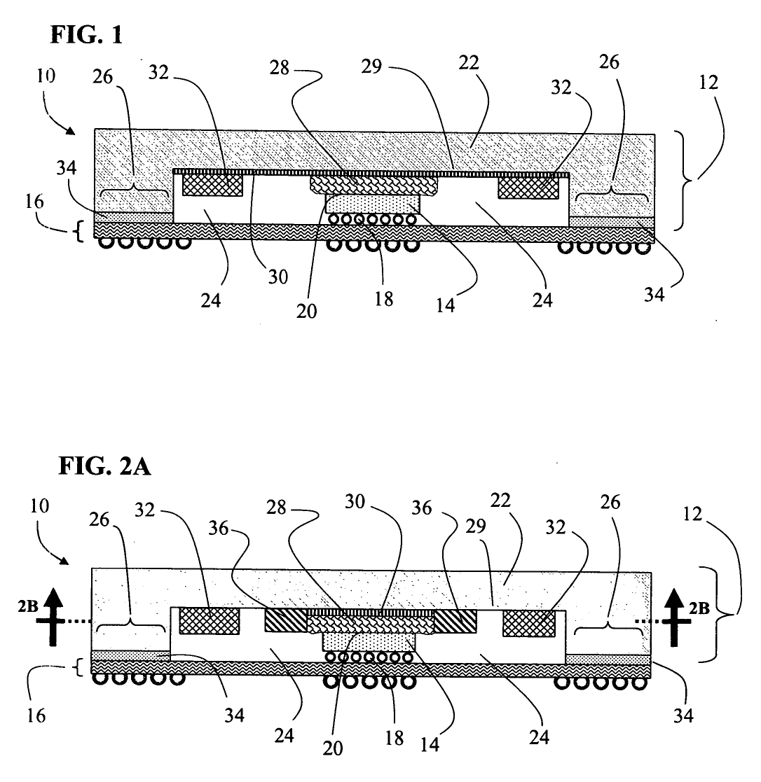

As seen in FIG. 1, an electronic component package 10, comprised of a thermal interface structure 12, electronic component 14, and package substrate 16, is illustrated. The electronic component 14 may be an IC chip (die) or other discrete device fabricated from silicon or a compound semiconductor material. The illustrated component 14 is a Flip Chip die which includes one face for electrical connection to the package substrate 16 (via flip chip solder balls 18) and an opposite face 20 to which a thermal interface structure 12 may be attached for removing generated heat.

The thermal interface structure includes a heat spreader lid 22 which may be metallic, composite or ceramic in composition. The lid is formed to include an underside cavity 24 and an outer flange 26. Within the lid cavity 24, a metal interface 28 is applied directly to the cavity surface 29 (by mechanical scrubbing or ultrasonic agitation) or to a diffusion barrier layer 30 which may be deposited on surface of the cavity 29. A metal (such as alloys of bismuth, gallium, indium and tin) which is liquid over the operating temperature of the electronic component is needed to allow the metal to adequately flow into all surface asperities of the lid cavity surface 29 and die 14. Suitable diffusion barrier layer materials include chromium, iron, molybdenum, nickel, niobium, tantalum or tungsten.

A corrosion inhibiting material 32, such as a moisture desiccant, vapor phase or liquid phase corrosion inhibitor, is disposed within the lid cavity 24. These materials, in powder or granular form, may be first applied to an absorbent or adhesive substrate/medium to facilitate deployment within the lid cavity 24.

Moisture desiccants can adsorb significant amounts of water even at low humidity levels. The reduction of humidity within the lid cavity 24 results in greatly reduced corrosion rates on the metal interface 28.

The moisture desiccant may be selected from the group consisting of silica gel; molecular sieve zeolites; activated clays, such as a montmorillonite clay; activated alumina; anhydrous calcium sulfate; anhydrous calcium chloride; anhydrous calcium bromide; anhydrous lithium chloride; anhydrous zinc chloride; anhydrous barium oxide; anhydrous calcium oxide and combinations thereof.

Vapor phase corrosion inhibitors are compounds transported in a closed environment to the site of corrosion by volatilization from a source. The vapors protect metallic surfaces through the deposition or condensation of a protective film or coating. Upon contact with the metal interface 28, the vapor of these salts condenses and is hydrolyzed by any moisture to liberate protective ions, thus mitigating any corrosion.

The vapor phase corrosion inhibitor may be selected from the group consisting of nitrites, benzoates, sulfonates, primary amines, secondary amines, tertiary amines, diamines, aliphatic polyamines, ethers, salts of quaternary ammonium compounds, amine salts, aromatic amines, nonaromatic heterocyclic amines, heterocyclic amines, alkanolamines, substituted alkanolamines, thiols, thioethers, sulfoxides, thiourea, substituted thioureas, substituted thiocarbonyl esters, phosphonium salts, arsonium salts, phosphates, sulfonates, molybdates, corresponding salts and combinations thereof.

The vapor phase corrosion inhibitor may additionally be selected from the group consisting of sodium nitrite, dicyclohexylamine, sodium benzoate, hexadecylpyridinium iodide, dodecylbenzyl quinolinium bromide, propargyl quinolinium bromide, cyclohexylammonium benzoate, ammonium benzoate, dicyclohexylammonium nitrite and dicyclohexylamine chromate, benzotriazole, mercaptobenzothiazole, sodium dinonylnaphthalene sulfonate, triethanolamine dinonylnaphthalene sulfonate, calcium dinonylnaphthalene sulfonate, magnesium dinonylnaphthalene sulfonate, barium dinonylnaphthalene sulfonate, zinc dinonylnaphthalene sulfonate, lithium dinonylnaphthalene sulfonate, ammonium dinonylnaphthalene sulfonate, ethylenediamine dinonylnaphthalene sulfonate, diethylenetriamine dinonylnaphthalene sulfonate, 2-methylpentanediamine dinonylnaphthalene sulfonate, sodium molybdate, corresponding salts and combinations thereof.

Liquid phase corrosion inhibitors blend with the liquid moisture present to protect surfaces through various mechanisms including the creation of passivation layers, raising the pH of the moisture, or reducing the electrical conductivity of the moisture layer. Liquid phase corrosion inhibitor candidates include sodium metaborate, sodium nitrite, sodium chromate and sodium silicate.

The lid 22 is attached to the electronic component package substrate 16 via the outer flange 26 and a continuous seal 34. Seal materials include silicones, polysulphides, polyurethanes, polyimides, polyesters, epoxides, cyanate esters, olefins and sealing glasses. A continuous seal between the heat spreader lid flange 26 and package substrate 16 greatly reduces the amount of moisture ingression within the lid cavity 24, resulting in reduced film formation and corrosion on the metal interface 28.

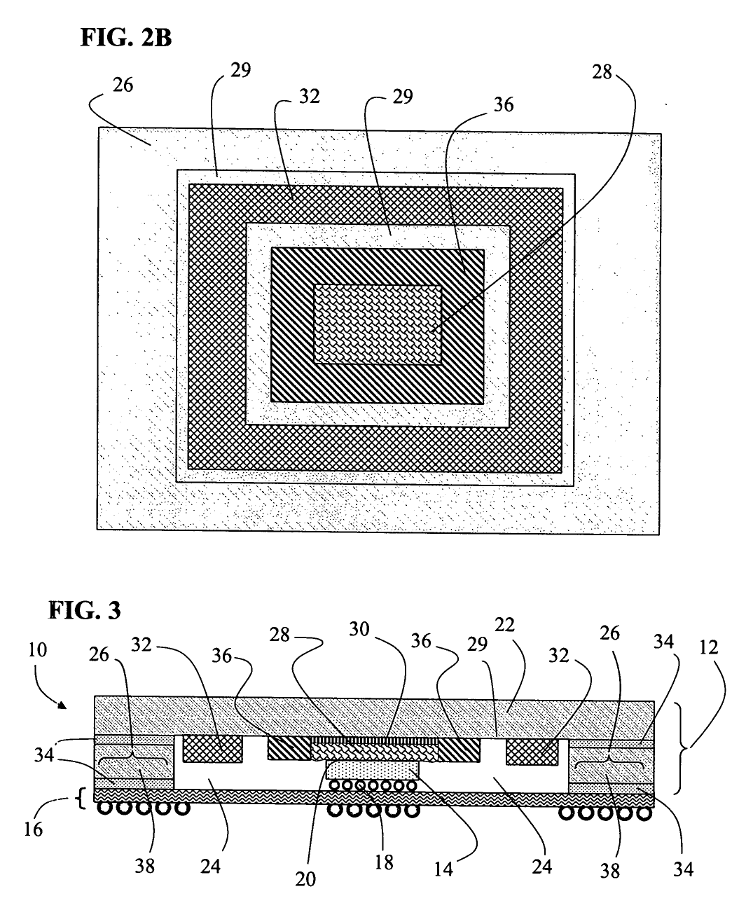

Reference is now made to FIGS. 2a and 2b wherein a containment band 36, which forms a physical barrier to metal interface migration, is illustrated within the electronic component package 10.

As shown in FIG. 2a, the containment band 36, affixed to the lid cavity surface 29, may be composed of a polymeric or fabric material which is coated (Teflon, for example) to mitigate any adhesion by the metal interface 28. The illustrated embodiment includes a diffusion barrier layer 30 which extends to the outer periphery of the metal layer 28 and the inner diameter of the containment band 36.

FIG. 2b (sectional view of FIG. 2a on lines 2b-2b) depicts the containment band 36 positioned around the periphery of the metal layer 28 along with corrosion inhibiting material 32 disposed within the heat spreader lid cavity 24 (on the lid cavity surface 29).

FIG. 3, similar to FIG. 2, illustrates an alternative heat spreader lid embodiment wherein the lid 22 may be joined to at least one additional ring or stiffener 38 (via an adhesive layer 34) thereby creating a heat spreader core cavity 24.

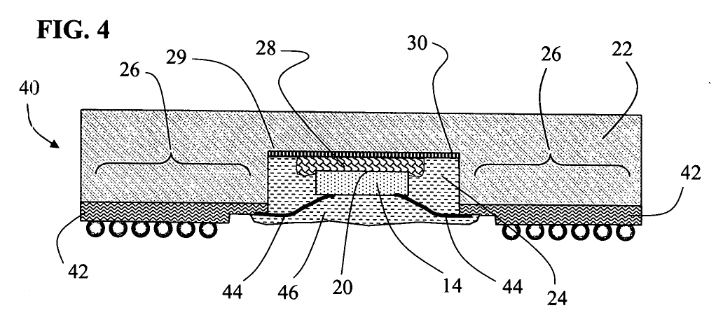

Reference is now made to FIG. 4 wherein another embodiment of the present invention is illustrated. The Cavity-Down style electronic component package 40 is comprised of a heat spreader core 22 formed with a cavity 24 and outer flange 26 on the core's underside. The core 22, which may be metallic, composite or ceramic in composition, provides structural integrity for a circuitry layer 42 which is attached to the outer flange 26. The IC die 14 includes a backside 20 which is attached to the cavity surface 29 within the core 22 via a metal interface 28. A diffusion barrier layer 30 may be deposited on the cavity surface 29 to mitigate the possibility of intermetallic formation between the core 22 and metal interface 28.

A plurality of metallic bond wires 44 provide electrical continuity between the die 14 and circuitry layer 42. An encapsulating material 46, disposed within the heat spreader core cavity 24, is applied over the IC die 14, the exposed portion of the metal interface 28 and bond wires 44, thereby protecting the metallic and semiconducting surfaces from moisture, contamination and physical damage. To maintain a precise position on the core 22, the IC die 14 may be partially fastened (at the corners or edges) to the cavity surface 29 by an adhesive prior to wire bonding or encapsulation.

Several embodiments of the present invention have been described. A person skilled in the art, however, will recognize that many other embodiments are possible within the scope of the claimed invention. For this reason, the scope of the invention is not to be determined from the description of the embodiments, but must instead be determined solely from the claims that follow.

1. A thermal interface structure for dissipating heat from an electronic component, the structure comprising:
(a) at least one heat spreader lid attachable to the electronic component, said lid comprising an underside which includes a cavity and an outer flange;
(b) a metal interface that is liquid over the operating temperature range of the electronic component, said metal applied to the heat spreader lid cavity and in contact with the electronic component;
(c) at least one corrosion inhibiting material disposed within the heat spreader lid cavity; and
(d) a continuous seal between the heat spreader lid flange and electronic component substrate.

2. The structure in claim 1 wherein the electronic component is a semiconductor chip and directly contacts said metal.

3. The structure in claim 1 wherein the said metal is applied to the heat spreader lid cavity by mechanical agitation.

4. The structure in claim 1 wherein the corrosion inhibiting material is a moisture desiccant.

5. The structure in claim 4 wherein the moisture desiccant is applied to an adhesive substrate prior to deployment within the heat spreader lid cavity.

6. The structure in claim 1 wherein the corrosion inhibiting material is a vapor phase corrosion inhibitor.

7. The structure in claim 6 wherein the vapor phase corrosion inhibitor is applied to an adhesive substrate prior to deployment within the heat spreader lid cavity.

8. The structure in claim 1 wherein the corrosion inhibiting material is a liquid phase corrosion inhibitor.

9. The structure in claim 8 wherein the liquid phase corrosion inhibitor is applied to an adhesive substrate prior to deployment within the heat spreader lid cavity.

10. The structure in claim 1 wherein the seal is selected from the group comprised of silicones, polysulphides, polyurethanes, polyimides, polyesters, epoxides, cyanate esters, olefins and sealing glasses.

11. The structure in claim 4 wherein the moisture desiccant is selected from the group comprised of silica gel; molecular sieve zeolites; activated clays, such as a montmorillonite clay; activated alumina; anhydrous calcium sulfate; anhydrous calcium chloride; anhydrous calcium bromide; anhydrous lithium chloride; anhydrous zinc chloride; anhydrous barium oxide; anhydrous calcium oxide and combinations thereof.

12. The structure in claim 6 wherein the vapor phase corrosion inhibitor is selected from the group comprised of nitrites, benzoates, sulfonates, primary amines, secondary amines, tertiary amines, diamines, aliphatic polyamines, ethers, salts of quaternary ammonium compounds, amine salts, aromatic amines, nonaromatic heterocyclic amines, heterocyclic amines, alkanolamines, substituted alkanolamines, thiols, thioethers, sulfoxides, thiourea, substituted thioureas, substituted thiocarbonyl esters, phosphonium salts, arsonium salts, phosphates, sulfonates, molybdates, corresponding salts and combinations thereof.

13. The structure in claim 6 wherein the vapor phase corrosion inhibitor is selected from the group comprised of sodium nitrite, dicyclohexylamine, sodium benzoate, hexadecylpyridinium iodide, dodecylbenzyl quinolinium bromide, propargyl quinolinium bromide, cyclohexylammonium benzoate, ammonium benzoate, dicyclohexylammonium nitrite and dicyclohexylamine chromate, benzotriazole, mercaptobenzothiazole, sodium dinonylnaphthalene sulfonate, triethanolamine dinonylnaphthalene sulfonate, calcium dinonylnaphthalene sulfonate, magnesium dinonylnaphthalene sulfonate, barium dinonylnaphthalene sulfonate, zinc dinonylnaphthalene sulfonate, lithium dinonylnaphthalene sulfonate, ammonium dinonylnaphthalene sulfonate, ethylenediamine dinonylnaphthalene sulfonate, diethylenetriamine dinonylnaphthalene sulfonate, 2-methylpentanediamine dinonylnaphthalene sulfonate, sodium molybdate, corresponding salts and combinations thereof.

14. The structure in claim 8 wherein the liquid phase corrosion inhibitor is selected from the group comprised of sodium metaborate, sodium nitrite, sodium chromate and sodium silicate.

15. A thermal interface structure for dissipating heat from an electronic component, the structure comprising:
(a) at least one heat spreader lid attachable to the electronic component, said lid comprising an underside which includes a cavity and an-outer flange,
(b) a diffusion barrier layer deposited within the heat spreader lid cavity;
(c) a metal interface that is liquid over the operating temperature range of the electronic component, said metal applied to the diffusion barrier layer within the heat spreader lid cavity and in contact with the electronic component;
(d) a containment band which forms a barrier to metal interface migration and is affixed to the heat spreader lid cavity and is positioned around the periphery of the metal layer region;
(e) at least one corrosion inhibiting material disposed within the heat spreader lid cavity; and
(f) a continuous seal between the heat spreader lid flange and electronic component substrate.

16. The structure in claim 15 wherein the electronic component is a semiconductor chip and directly contacts said metal interface.

17. The structure in claim 15 wherein the said metal is applied to the heat spreader lid cavity by mechanical agitation.

18. The structure in claim 15 wherein the corrosion inhibiting material is a moisture desiccant.

19. The structure in claim 18 wherein the moisture desiccant material is applied to an adhesive substrate prior to deployment within the heat spreader lid cavity.

20. The structure in claim 15 wherein the corrosion inhibiting material is a vapor phase corrosion inhibitor.

21. The structure in claim 20 wherein the vapor phase corrosion inhibitor is applied to an adhesive substrate prior to deployment within the heat spreader lid cavity.

22. The structure in claim 15 wherein the corrosion inhibiting material is a liquid phase corrosion inhibitor.

23. The structure in claim 22 wherein the liquid phase corrosion inhibitor is applied to an adhesive substrate prior to deployment within the heat spreader lid cavity.

24. The structure in claim 15 wherein the seal is selected from the group comprised of silicones, polysulphides, polyurethanes, polyimides, polyesters, epoxides, cyanate esters, olefins and sealing glasses.

25. The structure in claim 15 wherein the containment band structure includes a Teflon coating.

26. The structure in claim 18 wherein the moisture desiccant is selected from the group comprised of silica gel; molecular sieve zeolites; activated clays, such as a montmorillonite clay; activated alumina; anhydrous calcium sulfate; anhydrous calcium chloride; anhydrous calcium bromide; anhydrous lithium chloride; anhydrous zinc chloride; anhydrous barium oxide; anhydrous calcium oxide and combinations thereof.

27. The structure in claim 20 wherein the vapor phase corrosion inhibitor is selected from the group comprised of nitrites, benzoates, sulfonates, primary amines, secondary amines, tertiary amines, diamines, aliphatic polyamines, ethers, salts of quaternary ammonium compounds, amine salts, aromatic amines, nonaromatic heterocyclic amines, heterocyclic amines, alkanolamines, substituted alkanolamines, thiols, thioethers, sulfoxides, thiourea, substituted thioureas, substituted thiocarbonyl esters, phosphonium salts, arsonium salts, phosphates, sulfonates, molybdates, corresponding salts and combinations thereof.

28. The structure in claim 20 wherein the vapor phase corrosion inhibitor is selected from the group comprised of sodium nitrite, dicyclohexylamine, sodium benzoate, hexadecylpyridinium iodide, dodecylbenzyl quinolinium bromide, propargyl quinolinium bromide, cyclohexylammonium benzoate, ammonium benzoate, dicyclohexylammonium nitrite and dicyclohexylamine chromate, benzotriazole, mercaptobenzothiazole, sodium dinonylnaphthalene sulfonate, triethanolamine dinonylnaphthalene sulfonate, calcium dinonylnaphthalene sulfonate, magnesium dinonylnaphthalene sulfonate, barium dinonylnaphthalene sulfonate, zinc dinonylnaphthalene sulfonate, lithium dinonylnaphthalene sulfonate, ammonium dinonylnaphthalene sulfonate, ethylenediamine dinonylnaphthalene sulfonate, diethylenetriamine dinonylnaphthalene sulfonate, 2-methylpentanediamine dinonylnaphthalene sulfonate, sodium molybdate, corresponding salts and combinations thereof.

29. The structure in claim 22 wherein the liquid phase corrosion inhibitor is selected from the group comprised of sodium metaborate, sodium nitrite, sodium chromate and sodium silicate.

30. The structure of claim 15 wherein the diffusion barrier layer is selected from the group comprised of chromium, iron, molybdenum, nickel, niobium, tantalum and tungsten.

31. A thermal interface structure for dissipating heat from an IC die, the structure comprising:
(a) at least one heat spreader core attachable to the IC die, said core comprising an underside which includes a cavity and an outer flange;
(b) a circuit disposed on the outer flange surface;
(c) a metal interface that is liquid over the operating temperature range of the IC die, said metal applied between the IC die and heat spreader core cavity; and
(d) an encapsulating material applied over the IC die and metal interface within the heat spreader core cavity.

32. The structure of claim 31 wherein the IC die is partially fastened to the cavity by an adhesive.

33. The structure of claim 31 wherein a plurality of bond wires electrically connect the IC die to said circuit.

34. The structure of claim 31 wherein a diffusion barrier layer, selected from the group comprised of chromium, iron, molybdenum, nickel, niobium, tantalum and tungsten, is disposed between heat spreader core cavity and said metal interface.
